(19) United States
(12) Patent Application Publication
(10) Pub. No.: US 2022/0377894 A1
(43) Pub. Date: Nov. 24, 2022

(54) MOTHERBOARD

(71) Applicants: Inventec (Pudong) Technology Corporation, Shanghai (CN); INVENTEC CORPORATION, Taipei (TW)

(72) Inventors: Hui ZHU, Shanghai (CN); JiaQi Yuan, Shanghai (CN)

(21) Appl. No.: 17/348,920

(22) Filed: Jun. 16, 2021

(30) Foreign Application Priority Data
May 24, 2021 (CN) 202110564845.3

(51) Int. Cl. H05K 1/14; H05K 7/20

(52) U.S. Cl. CPC H05K 1/142; H05K 7/20754; H05K 2201/10356; H05K 2201/10492; H05K 2201/10325; H05K 2201/049

(57) ABSTRACT

A motherboard including a main circuit board, a first connector, a power circuit board and a second connector. The first connector is disposed on the main circuit board. A periphery of the power circuit board is spaced apart from a periphery of the main circuit board. The second connector is disposed on the power circuit board. The first cable electrically connects the first connector with the second connector.

### CROSS-REFERENCE TO RELATED APPLICATIONS

This non-provisional application claims priority under 35 U.S.C. § 119(a) on Patent Application No(s). 202110564845.3 filed in China, on May 24, 2021, the entire contents of which are hereby incorporated by reference.

### BACKGROUND OF THE INVENTION

### Technical Field of the Invention

The invention relates to a motherboard, more particularly to a motherboard applicable to electronic devices with different configurations.

### Description of the Related Art

A motherboard is commonly included in an electronic device, such as a server, to enable the operation of one or more electronic components disposed thereon. The one or more electronic components are, for example, processing units and memories. In general, the configuration of the motherboard is customized according to the requirements of the user of the server. Thus, the same motherboard is usually unable to be shared among servers with different configurations. That is, there may be a redundant area on the motherboard if the motherboard that is applicable to the server with a first configuration is applied in the server with a second configuration different from the first configuration.

Further, the customization of the motherboard sometimes enlarges the size of the motherboard and thus increases the manufacture cost of the motherboard.

### SUMMARY OF THE INVENTION

The invention provides a motherboard including a main circuit board and a power circuit board that are separate so as to allow the motherboard to be applicable to servers with different configurations and reduce the manufacture cost of the motherboard by preventing the size of the motherboard from being enlarged.

One embodiment of this invention provides a motherboard including a main circuit board, a first connector, a power circuit board and a second connector. The first connector is disposed on the main circuit board. A periphery of the power circuit board is spaced apart from a periphery of the main circuit board. The second connector is disposed on the power circuit board. The first cable electrically connects the first connector with the second connector.

According to the motherboard disclosed by the above embodiments, the main circuit board, the power circuit board, and the fan circuit board are separated from each other, and the periphery of the main circuit board is spaced apart from the periphery of the power circuit board and the periphery of the fan circuit board. Thus, the position relationship between the main circuit board, the power circuit board and the fan circuit board can be adjusted, such that the motherboard is applicable to different types of servers, and the redundant space on the motherboard is reduced. Also, the size of the main circuit board of the motherboard can be reduced so as to lower the manufacture cost of the motherboard, thereby enhancing the flexibility in the configuration of the motherboard.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a top view of a motherboard according to one embodiment of the invention; and

FIG. 2 is a top view of a motherboard according to another embodiment of the invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

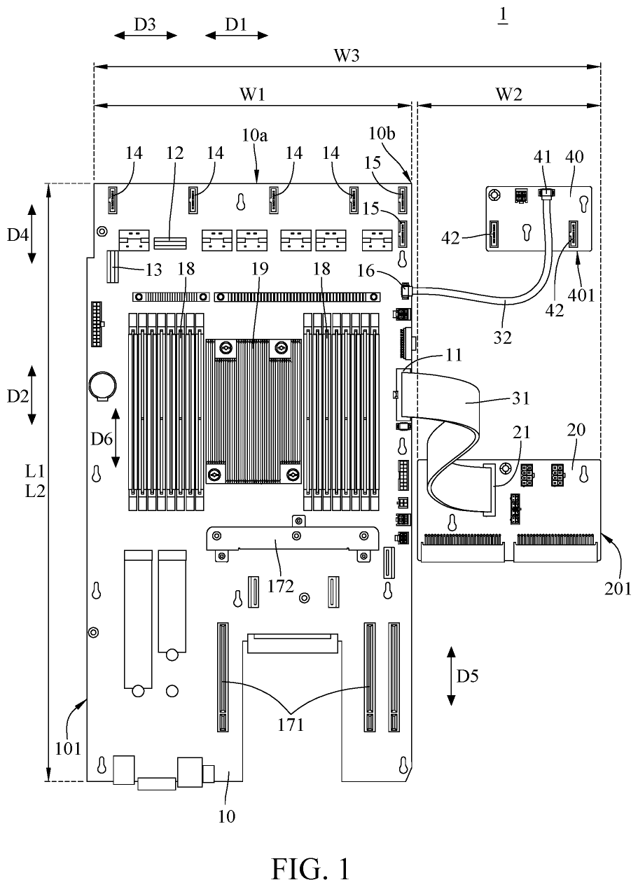

Please refer to FIG. 1, there is shown a top view of a motherboard 1 according to one embodiment of the invention.

In this embodiment, the motherboard 1 includes a main circuit board 10, a first connector 11, a power circuit board 20, a second connector 21 and a first cable 31. The power circuit board 20 and the main circuit board 10 are separated from each other. That is, the power circuit board 20 and the main circuit board 10 are not integrally formed. Also, a periphery 201 of the power circuit board 20 is spaced apart from a periphery 101 of the main circuit board 10. The first connector 11 is disposed on the main circuit board 10. The second connector 21 is disposed on the power circuit board 20. The first cable 31 electrically connects the first connector 11 with the second connector 21. The power circuit board 20 is configured for the installation of a power supply (not shown). The power supply can provide electricity to the main circuit board 10 via the power circuit board 20, the second connector 21, the first cable 31 and the first connector 11.

In a widthwise direction D1 of the main circuit board 10, the main circuit board 10 has a width W1. In a lengthwise direction D2 of the main circuit board 10, the main circuit board 10 has a length L1. The widthwise direction D1 of the main circuit board 10 is substantially perpendicular to the lengthwise direction D2 of the main circuit board 10. In this embodiment, the width W1 of the main circuit board 10 is about, for example, 10.58 inches and the length L1 of the main circuit board 10 is about, for example, 19.53 inches.

In the widthwise direction D1 of the main circuit board 10, the power circuit board 20 has a length W2. In the widthwise direction D1 of the main circuit board 10, the motherboard 1 has an overall width W3. The overall width W3 is substantially equal to the sum of the width W1 of the main circuit board 10 and the length W2 of the power circuit board 20. Specifically, in this embodiment, there is a negligible gap between the periphery 201 of the power circuit board 20 and the periphery 101 of the main circuit board 10 so that the overall width W3 is slightly greater than the sum of the width W1 and the length W2. However, in other embodiments where the periphery of the power circuit board is in physical contact with the periphery of the main circuit board, the overall width of the motherboard may be equal to the sum of the width of the main circuit board and the length of the power circuit board. In the lengthwise direction D2 of the main circuit board 10, the motherboard 1 has an overall length L2 that is substantially equal to the length L1 of the main circuit board 10. In this embodiment, the overall width W3 is approximately, for example, 16.7 inches. With the above configuration, the manufacture process of the motherboard 1 requires a machine merely capable of manufacturing a circuit board having a width no more than the width W1 and a length no more than the length L1 instead of the overall width W3 and the overall length L2. Also, the cost of the machine for manufacturing a circuit board is usually increased with the size of the circuit board. Thus, the manufacture cost of the motherboard 1 with the above configuration is low.

In this embodiment, the motherboard 1 further includes a first signal socket 12 and a second signal socket 13 that have the same specification. The first signal socket 12 and the second signal socket 13 are, for example, slimline connectors configured to transfer SATA signal. The first signal socket 12 is disposed on the main circuit board 10. The second signal socket 13 is disposed on the main circuit board 10. A first lengthwise direction D3 of the first signal socket 12 is different from a second lengthwise direction D4 of the second signal socket 13. Specifically, in this embodiment, the first lengthwise direction D3 of the first signal socket 12 is substantially perpendicular to the second lengthwise direction D4 of the second signal socket 13. The first lengthwise direction D3 of the first signal socket 12 is substantially parallel to the widthwise direction D1 of the main circuit board 10. The second lengthwise direction D4 of the second signal socket 13 is substantially parallel to the lengthwise direction D2 of the main circuit board 10.

Since the first lengthwise direction D3 of the first signal socket 12 is different from the second lengthwise direction D4 of the second signal socket 13, the first signal socket 12 can be easily differentiated from the second signal socket 13, thereby provide a mechanism of mistake-proof.

In this embodiment, the motherboard 1 further includes a plurality of first fan sockets 14. The first fan sockets 14 are disposed on the main circuit board 10. Also, the first fan sockets 14 are arranged along the widthwise direction D1 of the main circuit board 10 and are located adjacent to a short side 10a of the main circuit board 10. In this embodiment, there are four first fan sockets 14, but the invention is not limited thereto. In other embodiments, the quantity of the first fan sockets 14 may be adjusted according to actual requirements.

In this embodiment, the motherboard 1 further includes a plurality of second fan sockets 15. The second fan sockets 15 are disposed on the main circuit board 10. Also, the second fan sockets 15 are arranged along the lengthwise direction D2 of the main circuit board 10 and are located adjacent to a corner 10b of the main circuit board 10. In this embodiment, there are two second fan sockets 15, but the invention is not limited thereto. In other embodiments, the quantity of the second fan sockets 15 may be adjusted according to actual requirements.

In this embodiment, the motherboard 1 may further include a fan circuit board 40, a third connector 16, a fourth connector 41, a second cable 32 and other second fan sockets 42. The fan circuit board 40, the power circuit board 20 and the main circuit board 10 are separated from one another. That is, the fan circuit board 40, the power circuit board 20 and the main circuit board 10 are not integrally formed. Further, in this embodiment, a periphery 401 of the fan circuit board 40 is spaced apart from the periphery 101 of the main circuit board 10 and the periphery 201 of the power circuit board 20. The third connector 16 is disposed on the main circuit board 10. The fourth connector 41 is disposed on the fan circuit board 40. The second cable 32 electrically connects the third connector 16 with the fourth connector 41. The second fan sockets 42 are disposed on the fan circuit board. In this embodiment, there are two second fan sockets 42, but the invention is not limited thereto. In other embodiments, the quantity of the second fan sockets 42 may be adjusted according to actual requirements.

In this embodiment, the motherboard 1 further includes a plurality of PCI-E sockets 171 and a handle 172. The PCI-E sockets 171 and the handle 172 are disposed on the main circuit board 10. A lengthwise direction D5 of each PCI-E socket 171 is substantially perpendicular to the widthwise direction D1 of the main circuit board 10 (i.e., substantially parallel to the lengthwise direction D2 of the main circuit board 10). The handle 172 is located on a side of each PCI-E socket 171 along lengthwise direction D5 of each PCI-E socket 171. The handle 172 is configured for the fixation of a plurality of PCI-E expansion cards that are plugged into the PCI-E sockets 171.

In this embodiment, the motherboard 1 further includes a plurality of memory connectors 18 and a processor socket 19. The memory connectors 18 are disposed on the main circuit board 10 and are arranged along the widthwise direction D1 of the main circuit board 10. The lengthwise direction D6 of each memory connector 18 is substantially perpendicular to the widthwise direction D1 of the main circuit board 10 (i.e., substantially parallel to the lengthwise direction D2 of the main circuit board 10). The processor socket 19 is disposed on the main circuit board 10 and is located between two adjacent memory connectors 18.

The main circuit board 10, the power circuit board 20 and the fan circuit board 40 may be disposed on a tray (not shown) of a server. The power circuit board 20 and the fan circuit board 40 may be located on the same side of the main circuit board 10. Alternatively, the position relationship among the main circuit board 10, the power circuit board 20 and the fan circuit board 40 may be adjusted according to the size or the specification of the tray. In this embodiment, the utilization rate of the motherboard 1 reaches 87 percent. Also, comparing to other motherboards having the overall length L2 and the overall width W3, the cost of the motherboard 1 provided by this embodiment is decreased by 60 percent or more.

During the operation of the motherboard 1, since both of the memory connector 18 and the processor socket 19 are disposed on the main circuit board 10, a high frequency signal can be transferred between the memory connector 18 and the processor socket 19 with less attenuation. Additionally, the frequency of the power signal required by the main circuit board 10 is very low. Thus, the power signal can be stably transferred to the main circuit board 10 even though the main circuit board 10 and the power circuit board 20 are electrically connected to each other by the first cable 31.

During the operation of the motherboard 1, there may be four main fans (not shown) respectively installed in the first fan sockets 14, and there may be two secondary fans (not shown) respectively installed in the second fan sockets 42. In general, the four main fans are enabled to dissipate the heat generated by the motherboard 1. When the heat generated by the motherboard 1 is increased, the two secondary fans can also be enabled so as to cooperate with the four main fans.

Alternatively, the two secondary fans (not shown) may be respectively installed in the second fan sockets 15.

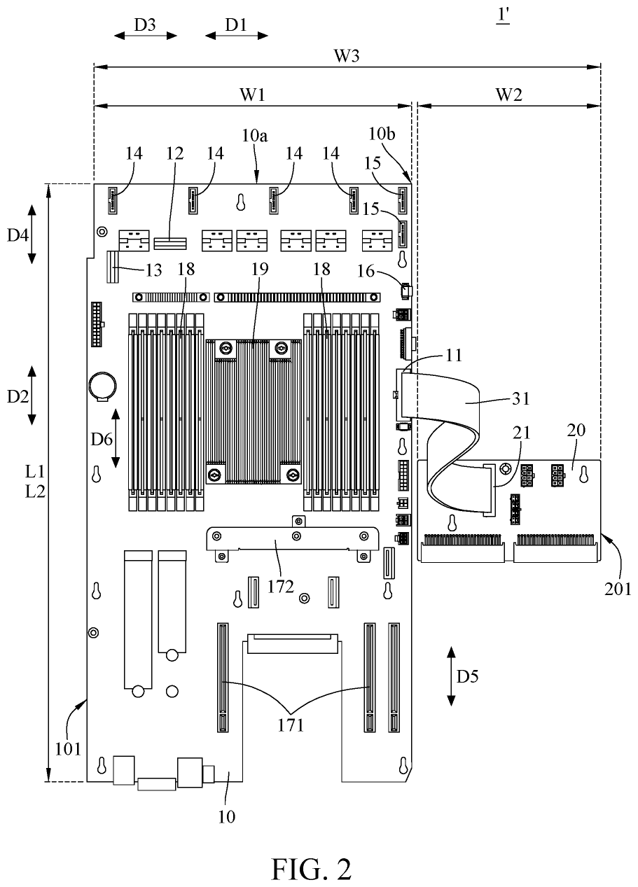

Please refer to FIG. 2, there is shown a top view of a motherboard according to another embodiment of the invention.

The motherboard 1′ provided by this embodiment and the motherboard 1 shown in FIG. 1 are similar in structure and the main difference therebetween is that the motherboard 1′ does not include the fan circuit board 40 and the second cable 32 that are shown in FIG. 1.

In this embodiment, in a widthwise direction D1 of the main circuit board 10′, the main circuit board 10′ has a width W1 that is about 10.58 inches. In this embodiment, in a lengthwise direction D2 of the main circuit board 10′, the main circuit board 10′ has a length L1 that is about 19.53 inches.

In the widthwise direction D1 of the main circuit board 10, the power circuit board 20 has a length W2. In the widthwise direction D1 of the main circuit board 10, the motherboard 1′ has an overall width W3. The overall width W3 is substantially equal to the sum of the width W1 of the main circuit board 10 and the length W2 of the power circuit board 20. Specifically, in this embodiment, there is a negligible gap between the periphery 201 of the power circuit board 20 and the periphery 101 of the main circuit board 10 so that the overall width W3 is slightly greater than the sum of the width W1 and the length W2. However, in other embodiments where the periphery of the power circuit board is in physical contact with the periphery of the main circuit board, the overall width of the motherboard may be equal to the sum of the width of the main circuit board and the length of the power circuit board. In the lengthwise direction D2 of the main circuit board 10, the motherboard 1′ has an overall length L2 that is substantially equal to the length L1 of the main circuit board 10. In this embodiment, the overall width W3 is, for example, 16.7 inches. With the above configuration, the manufacture process of the motherboard 1′ requires a machine capable of manufacturing a circuit board having the width W1 and the length L1 instead of a circuit board having the overall width W3 and the overall length L2. Also, the manufacture cost of a circuit board is usually increased with the size of that circuit board. Thus, the manufacture cost of the motherboard 1′ is reduced.

The main circuit board 10 and the power circuit board 20 may be disposed on a tray (not shown) of a server. The power circuit board 20 may be located on a side of the main circuit board 10. Alternatively, the position relationship between the main circuit board 10 and the power circuit board 20 may be adjusted according to the size or the specification of the tray. In this embodiment, the utilization rate of the motherboard 1 reaches 87 percent. Also, comparing to other motherboards having the overall length L2 and the overall width W3, the cost of the motherboard 1′ provided by this embodiment is decreased by 60 percent or more.

During the operation of the motherboard 1′, there may be four main fans (not shown) respectively installed in the first fan sockets 14, and there may be two secondary fans (not shown) respectively installed in the second fan sockets 42. In general, the four main fans are enabled to dissipate the heat generated by the motherboard 1′. When the heat generated by the motherboard 1′ is increased, the two secondary fans can also be enabled so as to cooperate with the four main fans.

According to the motherboard disclosed by the above embodiments, the main circuit board, the power circuit board, and the fan circuit board are separated from each other, and the periphery of the main circuit board is spaced apart from the periphery of the power circuit board and the periphery of the fan circuit board. Thus, the position relationship between the main circuit board, the power circuit board and the fan circuit board can be adjusted, such that the motherboard is applicable to different types of servers, and the redundant space on the motherboard is reduced. Also, the size of the main circuit board of the motherboard can be reduced so as to lower the manufacture cost of the motherboard, thereby enhancing the flexibility in the configuration of the motherboard. Also, the fan circuit board can be omitted according to actual requirements. Further, since the lengthwise direction of the first signal socket is different from the lengthwise direction of the second signal socket, a mechanism of mistake-proof is provided for the first signal socket and the second signal socket of the same specification proof.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A motherboard, comprising:
a main circuit board;
a first connector, disposed on the main circuit board;
a power circuit board, a periphery of the power circuit board spaced apart from a periphery of the main circuit board;
a second connector, disposed on the power circuit board; and
a first cable, electrically connecting the first connector with the second connector.

2. The motherboard according to claim 1, wherein the main circuit board has a width and a length, the power circuit board has a length, an overall length of the motherboard is equal to the length of the main circuit board, an overall width of the motherboard is substantially equal to a sum of the width of the main circuit board and the length of the power circuit board.

3. The motherboard according to claim 1, further comprising a first signal socket and a second signal socket, wherein a specification of the first signal socket is the same as a specification of the second signal socket, the first signal socket is disposed on the main circuit board, the second signal socket is disposed on the main circuit board, a first lengthwise direction of the first signal socket is different from a second lengthwise direction of the second signal socket.

4. The motherboard according to claim 3, wherein the second lengthwise direction of the second signal socket is substantially perpendicular to the first lengthwise direction of the first signal socket.

5. The motherboard according to claim 3, wherein the first lengthwise direction of the first signal socket is substantially parallel to a widthwise direction of the main circuit board.

6. The motherboard according to claim 1, further comprising a plurality of first fan sockets, wherein the plurality of first fan sockets are disposed on the main circuit board, the plurality of first fan sockets are arranged along a widthwise direction of the main circuit board and are located adjacent to a short side of the main circuit board.

7. The motherboard according to claim 6, further comprising a plurality of second fan sockets, wherein the plurality of second fan sockets are disposed on the main circuit board, the plurality of second fan sockets are arranged along a lengthwise direction of the main circuit board that is substantially perpendicular to the widthwise direction of the main circuit board, the plurality of second fan sockets are located adjacent to a corner of the main circuit board.

8. The motherboard according to claim 6, further comprising a fan circuit board, a third connector, a fourth connector and a second cable, wherein the third connector is disposed on the main circuit board, a periphery of the fan circuit board is spaced apart from the periphery of the main circuit board, the fourth connector is disposed on the fan circuit board, the second cable electrically connects the third connector with the fourth connector.

9. The motherboard according to claim 8, further comprising a plurality of second fan sockets that are disposed on the fan circuit board.

10. The motherboard according to claim 1, further comprising a PCI-E socket and a handle, wherein the PCI-E socket and the handle are disposed on the main circuit board, a lengthwise direction of the PCI-E socket is substantially perpendicular to a widthwise direction of the main circuit board, the handle is located on a side of the PCI-E socket along the lengthwise direction of the PCI-E socket, the handle is configured for a fixation of a PCI-E expansion card that is plugged into the PCI-E socket.
